(19) United States
(12) Patent Application Publication
(10) Pub. No.: US 2006/0027828 A1
(43) Pub. Date: Feb. 9, 2006

(54) Light-emitting diode lamp

(75) Inventor: Satoru Kikuchi, Tokyo (JP)

Correspondence Address: BROWDY AND NEIMARK, P.L.L.C.;624 NINTH STREET, NW, SUITE 300, WASHINGTON, DC, 20001-5303, US

(73) Assignee: Citizen Electronics Co., Ltd., Fujiyoshida-shi (JP)

(21) Appl. No.: 11/198,389

(22) Filed: Aug. 8, 2005

(30) Foreign Application Priority Data
Aug. 6, 2004 (JP) P2004-230104

(51) Int. Cl. H01L 33/00

(52) U.S. Cl. 257/99

(57) ABSTRACT

An LED lamp (30) comprising a circuit board (22) on which electrode patterns are formed, a reflective frame (31) provided on the circuit board (22) and having a concave portion (32), a light emitter (27) mounted in the concave portion (32), a translucent sealing plate (3) disposed on an upper surface of the reflective frame (31) above the light emitter (27) and including a lens part (8), and a protecting member (11) disposed on a surface having an emission area of the translucent sealing plate (3) and protecting the lens part (8), the protecting member (11) including an opening (11a) having an axis extending in a direction of thickness of the protecting member, an inner edge of the opening (11) being set to lie at an outer peripheral portion of a lens effective diameter (8a) of the lens part (8) or outside the lens effective diameter (8a).

### CROSS-REFERENCE TO THE RELATED APPLICATION

This application is based on and claims priority from Japanese Patent Application No. 2004-230104 filed on Aug. 6, 2004, the disclosure of which is incorporated herein by reference in its entirety.

### BACKGROUND OF THE INVENTION

1. Field of the Invention

The present invention relates to a light-emitting diode (LED) lamp, more specifically to an LED lamp configured to protect a lens for focusing, dispersing or the like of light emitted from a light emitter.

2. Description of Related Art

An LED lamp is widely used in mobile terminals, home appliances, lighting, vehicles, automatic dispensers or the like. An LED lamp in which light emitted from a light emitter is emitted through a lens to the outside is well known as a first example of a conventional LED lamp (for example, see Japanese Patent Application Laid-Open Disclosure Number 2004-327955, paragraph 0029, FIG. 9).

FIG. 11 illustrates the first example of a conventional LED lamp.

As shown in FIG. 11, the LED lamp 71 comprises a circuit board 22 on which electrode patterns are provided, a reflective frame 31 mounted on the circuit board 22 and including a concave portion 32 having a tapered inner peripheral surface, and a light emitter 27 disposed at a central portion in the concave portion 32.

A reflecting surface 33 made of nickel plating or other silver plating is formed on the inner peripheral surface of the concave portion 32 so that light emitted from the light emitter 27 can be efficiently reflected in an upward direction. A translucent sealing plate 74 is disposed on the reflective frame 31 and an air layer is provided between the light emitter 27 and the translucent sealing plate 74. A lens part 76 comprising a rough surface is provided on the translucent sealing plate 74. A micro-lens, a Fresnel lens or the like may be used instead of the rough surface.

With the above-mentioned structure, light emitted upward from the light emitter 27 and reflected by the reflecting surface 33 is focused by the lens part 76 to increase the amount of light emitted from the light emitter 27 to the outside.

Moreover, a surface-mounted LED lamp in which a circuit board and a reflective frame are integrally formed is well known as a second example of a conventional LED lamp (for example, see Japanese Patent Laid-Open Disclosure Number 2003-158301, page 3, FIG. 1).

FIG. 12 illustrates the surface-mounted LED lamp, the second example of a conventional LED lamp.

As shown in FIG. 12, the LED lamp 1 includes a circuit board 2 having conductive patterns 5 and an LED element 10 as a light emitter, which is mounted on the circuit board 2. A translucent sealing plate 3 is attached to the circuit board 2. The circuit board 2 is formed as an MID (Molded Interconnection Device) which is a three-dimensional shaped circuit component forming a conductive circuit and electrodes on a resin-molded article. The LED element 10 is mounted on a bottom surface of a concave portion provided in the package. Two electrodes of the LED element 10 are mounted on the conductive patterns 5 of the circuit board 2 through bumps 7 by flip-chip bonding.

The translucent sealing plate 3 is made of a translucent material such as translucent glass, translucent resin or the like, has a sheet shape or planar plated shape, and includes a lens part 8 such as a Fresnel lens, micro-lens or the like. The LED element 10 is protected by the translucent sealing plate 3 to accomplish a secure transmission of light and a high focusing of light to the outside.

However, in each of the conventional LED lamps described above, the lens part of the translucent sealing plate is exposed outside the LED lamp, so that the lens part is easily broken by mechanical impact due to contact with the exterior. When the lens part is broken, the problems arise that the LED lamp cannot be used or that there is a deterioration in the optical characteristics of the light emitted from the lens.

### SUMMARY OF THE INVENTION

The object of the present invention is to provide an LED lamp capable of protecting a lens part of a translucent sealing plate, and achieving high optical characteristics of the light emitted from the lens part, excellent brightness characteristics of the light, and long-term reliability of the LED lamp.

To accomplish this object, according to one embodiment of the present invention, the LED lamp comprises a circuit board including electrode patterns, a light emitter provided on the circuit board, a reflective frame disposed on the circuit board and having a reflecting surface formed to surround the light emitter, a translucent sealing plate provided on an upper surface of the reflective frame, above the light emitter, and including a lens part, and a protecting member disposed on a periphery of an emission area of the translucent sealing plate and configured to protect the lens part of the translucent sealing plate. Therefore, the translucent sealing plate, in particular the lens part provided on the translucent sealing plate, is effectively protected by the protecting member.

### BRIEF DESCRIPTION OF THE DRAWINGS

FIG. 1 is a sectional view showing an LED lamp according to a first embodiment of the present invention.

FIG. 2 is a sectional view showing another embodiment of the LED lamp based on the first embodiment of the present invention.

FIG. 3 is a sectional view showing an LED lamp according to a second embodiment of the present invention.

FIG. 4 is a sectional view showing an LED lamp according to a third embodiment of the present invention.

FIG. 5 is a sectional view showing another embodiment of a translucent sealing plate in the LED lamps based on the above-mentioned embodiments.

FIG. 6A is a perspective view showing an LED lamp according to a fourth embodiment of the present invention.

FIG. 6B is a sectional view taken along the A-A line in FIG. 6A.

FIG. 7 is a perspective view showing the LED lamp according to the fourth embodiment of the present invention.

FIG. 8 is a sectional view showing the LED lamp according to the fourth embodiment of the present invention.

FIG. 9 is a top plan view showing the LED lamp according to the fourth embodiment of the present invention.

FIG. 10 is an exploded perspective view showing the LED lamp according to the fourth embodiment of the present invention.

FIG. 11 is a sectional view showing an LED lamp according to a first conventional example.

FIG. 12 is a sectional view showing an LED lamp according to a second conventional example.

### DETAILED DESCRIPTION OF THE PREFERRED EMBODIMENTS

Some preferred embodiments of the present invention will be explained in detail with reference to the accompanying drawings hereinafter.

### First Embodiment

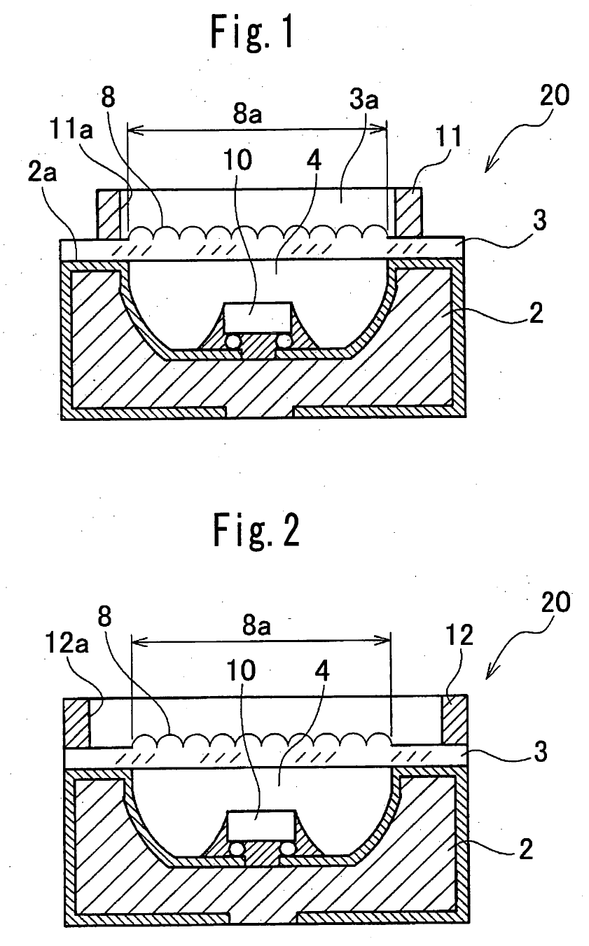

FIG. 1 shows an LED lamp 20 according to a first embodiment of the present invention. The LED lamp 20 includes a circuit board 2 and a light emitter 10 mounted on the circuit board 2. The circuit board 2 in this embodiment is formed by the same method as a three-dimensional shaped circuit component (Molded Interconnection Device) in which a board, and a conductive circuit and electrodes provided on the board (not illustrated) are integrally formed.

Hereinafter, the circuit board will be referred to as an MID board.

The light emitter 10 comprises at least one LED element in this embodiment.

The MID board 2 has a concave portion 4, and the LED element 10 is disposed on a bottom surface of the concave portion 4 through a suitable connecting mechanism so as to be connected with the electrodes provided on the circuit board.

A translucent sealing plate 3 for covering the LED element 10 is disposed on an upper surface 2a of the MID board 2, and the translucent sealing plate 3 has an emission area 3a for emitting light from the LED element 10 to the outside. A lens part 8 such as a Fresnel lens, micro lens or the like is provided on the emission area 3a.

A protecting member 11 is disposed around a predetermined emission area of the translucent sealing plate 3 without shielding light emitted from the emission area to protect the translucent sealing plate 3. The protecting member 11 is attached to the translucent sealing plate 3 so as to protect the lens part 8 of the translucent sealing plate 3 in the embodiment. For example, the protecting member 11 has an opening 11a which passes through the protecting member. The inner diameter of the opening 11a is set to be generally equal to or larger than a lens effective diameter 8a of the lens part 8 (see FIG. 1).

Thereby, an inner edge of the opening 11a of the protecting member 11 is disposed to lie at an outer peripheral part of the lens effective diameter 8a of the lens part 8 or outside the lens effective diameter 8a.

As described above, in the LED lamp 20 in the embodiment, the lens part 8 of the translucent sealing plate 3 is protected by the protecting member 11, so that a scratch or the like can be prevented from occurring on the lens part 8 of the translucent sealing plate 3 by an external impact, and deterioration in the optical characteristics of the lens part 8 can be prevented.

Consequently, it is possible to achieve an LED lamp 20 having improved brightness characteristics and long-term reliability.

Instead of the protecting member 11, a protecting member 12 may be used, an inner diameter of an opening 12a of the protecting member 12 may be set to be considerably larger than the lens effective diameter 8a of the lens part 8 of the translucent sealing plate 3, an inner edge of the opening 12a may be positioned outside the lens effective diameter 8a of the lens part 8 and an outer diameter of the protecting member may be disposed along an outer periphery of the translucent sealing plate 3, as shown in FIG. 2.

In this embodiment, the same advantageous effect as in the first embodiment can be achieved. Similarly, the same advantageous effect can be achieved with the structure in which the translucent sealing plate 3 and the protecting member 12 are integrally formed.

### Second Embodiment

In an LED lamp according to a second embodiment of the present invention, a protecting member differs in structure from that in the first embodiment, but in other aspects it is the same as the LED lamp in the first embodiment. Therefore, the same reference numbers are attached to the parts which are identical to those in the first embodiment, and a description thereof is omitted.

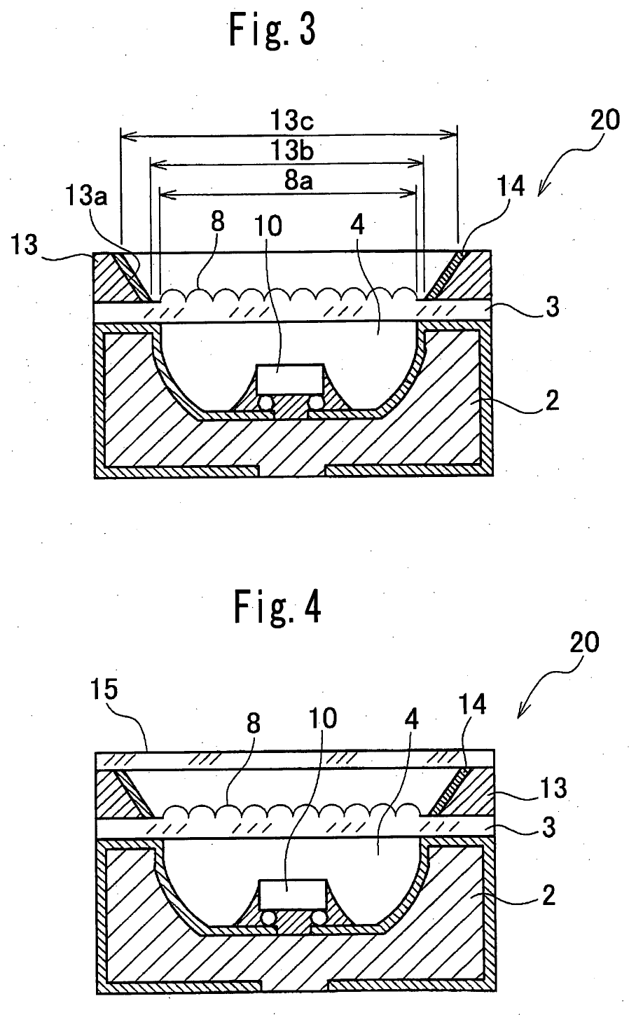

The LED lamp according to the second embodiment is described below, referring to FIG. 3.

As shown in FIG. 3, an inner diameter of an opening 13a of the protecting member 13 of the LED lamp 20 in the second embodiment is set to become gradually larger from one surface adjacent to the translucent sealing plate 3 toward the other surface of the protecting member opposing the one surface. In other words, the opening 13a of the protecting member 13 has a smaller diameter 13b adjacent to the translucent sealing plate 3 and a larger diameter 13c away from the translucent sealing plate 3. The opening 13a includes an inner surface which has a generally truncated cone shape and is jointed integrally with the translucent sealing plate 3 at the position of the lesser diameter 13b.

A light-reflecting layer 14 is formed on the entire area of the truncated cone-shaped inner surface of the protecting member 13 in the opening 13a. The light-reflecting layer 14 provided on the inner surface of the protecting member 13 in the opening 13a is surface-treated by plating or vacuum evaporation of a metallic film, for example.

Although the example has been described in which the inner surface of the protecting member 13 in the opening 13a has a generally truncated cone shape, this embodiment is not limited to this shape, and the inner peripheral surface may be formed as a truncated pyramidal shape, or a curved surface such as a portion of a spherical surface, a portion of a paraboloidal surface, aspheric surface or the like.

As described above, in the LED lamp in the embodiment, the inner diameter of the opening 13a of the protecting member 13 is set to become gradually larger from one surface of the protecting member adjacent to the translucent sealing plate 3 toward the other surface of the protecting member opposing the one surface, the inner surface of the protecting member 13 in the opening 13a has a generally truncated cone shape, and the light-reflecting layer 14 is formed on the truncated cone-shaped inner surface of the protecting member in the opening 13a, so that the light emitted from the opening 13a is focused to be a beam.

Consequently, the light emitted from the lens part 8 is reflected and the focusing characteristics at the reflecting layer 14 are increased. It is possible to achieve an LED lamp 20 having excellent brightness characteristics and long-term reliability in the same way as in the first embodiment.

### Third Embodiment

An LED lamp according to a third embodiment of the present invention has a structure in which a translucent protecting plate is provided on an upper surface of the protecting member 13, but in other aspects it is the same as the LED lamp in the second embodiment. Therefore, the same reference numbers are attached to the parts which are identical to those in the second embodiment, and a description thereof is omitted.

The LED lamp according to the third embodiment is described below, referring to FIG. 4.

As shown in FIG. 4, the LED lamp 20 according to the third embodiment includes a translucent protecting plate 15 provided on an upper surface of the protecting member 13. The translucent protecting plate 15 is made of a sheet-like or flat plate-like acrylic, a translucent resinous material of polycarbonate or the like, or glass material, and the translucent protecting plate 15 is formed integrally with the upper surface of the protecting member 13.

Meanwhile, it is preferable to use glass material because it does not scratch easily and has high light transmission.

As described above, in the LED lamp 20 according to the embodiment, the translucent protecting plate 15 is provided on the upper surface of the protecting member 13, so that dust is prevented from becoming attached to the lens part 8 of the translucent sealing plate 3 and degradation of the optical characteristics of the lens part 8 can be prevented. Moreover, an ultraviolet protection material may be contained in the protecting member 13 to increase weatherability. Furthermore, highly reflected light with increased focusing characteristics can be emitted from the lens part, in the same way as in the second embodiment. Therefore, it is possible to achieve an LED lamp having excellent brightness characteristics and long-term reliability.

In this embodiment, although the example has been described in which the translucent protecting plate 15 is provided on the upper surface of the protecting member 13, the same advantageous effect can be obtained even if the translucent protecting plate 15 is provided on the protecting members 11 or 12 in the first embodiment.

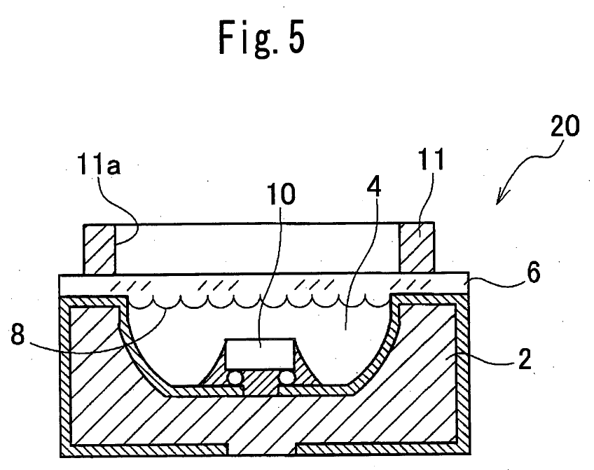

On the other hand, although the lens part 8 of the translucent sealing plate 3 in each embodiment is disposed to face the surface of the translucent protecting plate 15, the same advantageous effect can be obtained even if the lens part 8 is disposed to face the LED element 10, as shown in FIG. 5.

### Fourth Embodiment

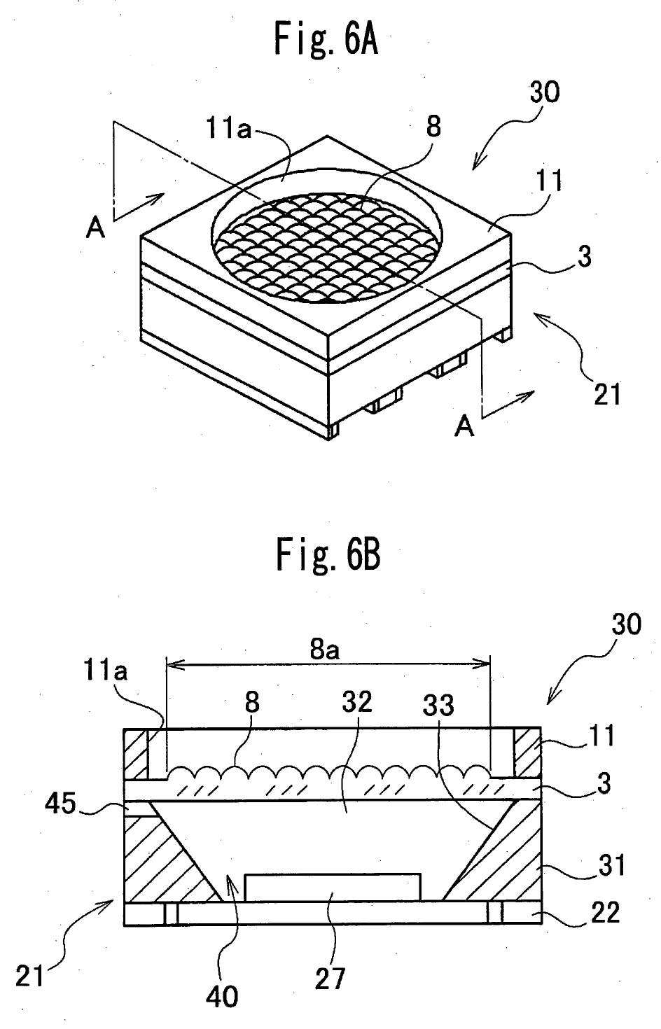

FIGS. 6A and 6B illustrate an LED lamp according to a fourth embodiment of the present invention.

As shown in FIGS. 6A and 6B, an LED lamp 30 in this embodiment includes a main body 21 of the LED lamp and a translucent sealing plate 3 which is provided on an upper surface of the main body 21 and has a lens part 8. A protecting member 11 similar to the protecting member in the first embodiment is disposed on a surface having an emission area of the translucent sealing plate 3.

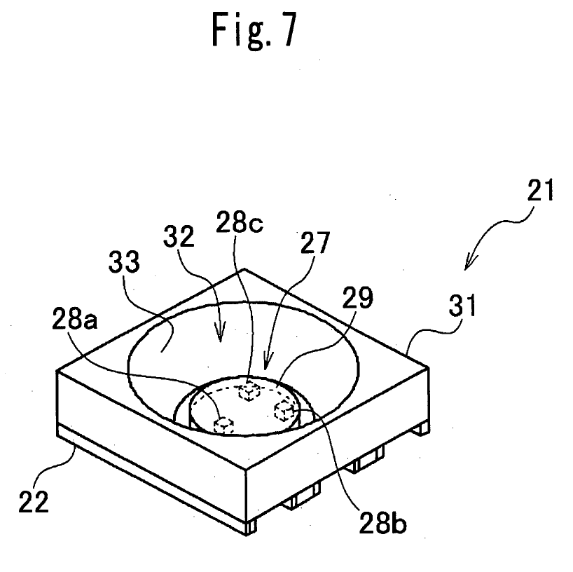

The main body 21 of the LED lamp comprises a circuit board 22 on which three sets of anode and cathode electrodes are formed, a light emitter 27 mounted on the circuit board, and a reflective frame 31 including a reflecting surface 33 configured to surround the light emitter 27, as shown in FIGS. 7 to 10.

The circuit board 22 has a square shape and is made of glass epoxy or BT resin or the like, as shown in FIG. 9. Anode electrodes A1, A2 and A3 and cathode electrodes K1, K2 and K3 are disposed at opposed sides of the circuit board 22 and formed by through-holes. Lead patterns of the anode electrodes A1 to A3 and cathode electrodes K1 to K3 are formed to extend from one side of the circuit board 22 to a central portion of the circuit board 22. Three LED elements 28a, 28b and 28c are mounted on the circuit board 22. More specifically, the LED element 28a is connected by bonding wires between the lead patterns A1 and K1, the LED element 28b is connected by bonding wires between the lead patterns A2 and K2, and the LED element 28c is connected by bonding wires between the lead patterns A3 and K3.

In this embodiment, the light emitter 27 comprises the three LED elements 28a, 28b and 28c, and a transparent or translucent resinous material 29 for sealing the three LED elements. The LED elements 28a, 28b and 28c are formed from a semiconductor of a gallium nitride related compound and disposed at equal intervals in a triangular shape at the central portion of the circuit board 22, as shown in FIG. 9.

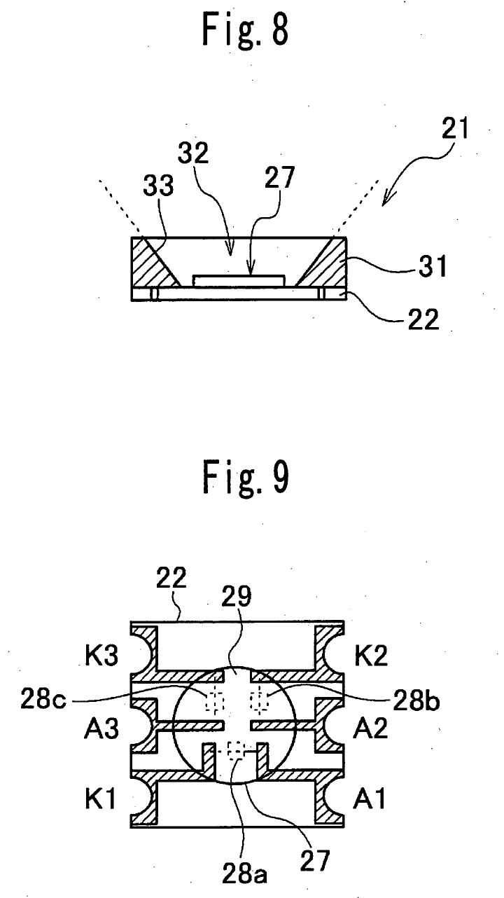

The reflective frame 31 is a component with generally the same planar shape as the circuit board 22, as shown in FIGS. 7 and 8 and disposed on the circuit board 22. In addition, the reflective frame 31 is of greater thickness than the circuit board 22 and includes a cone-shaped concave portion 32 which is formed at a central portion of the reflective frame and disposed to surround the light emitter 27. The concave portion 32 has a circular inner peripheral surface for equally focusing light emitted from the light emitter 27 and a taper that broadens upwardly.

The light emitted from the light emitter 27 can be reflected efficiently in an upward direction by forming a reflecting surface 33 made of nickel plating or other silver related plating on the inner peripheral surface of the concave portion 32. The shape and angle of inclination of the reflecting surface 33 are set suitably according to the specifications of the main body 21 of the LED lamp, but it is preferable that the reflecting surface has a hemispherical shape centering on the light emitter 27 and is inclined upwardly in the range of 40 to 80 degrees in order to equally illuminate a subject located at a certain distance when the LED lamp is used as a flash light source of a camera.

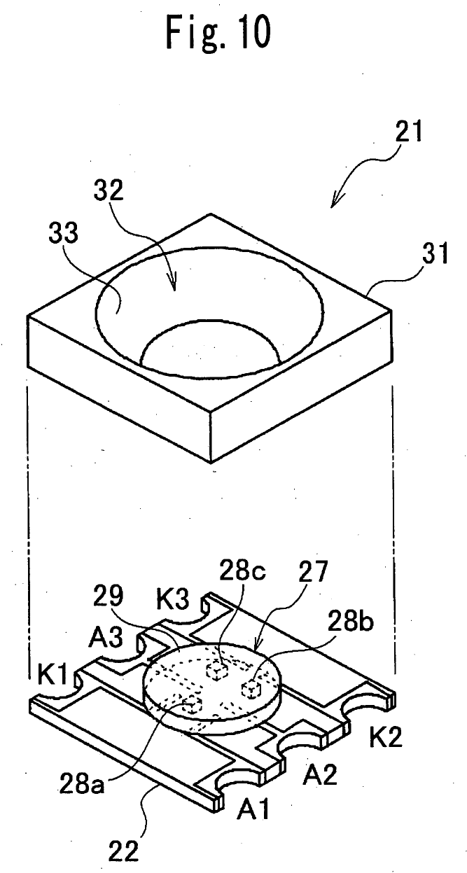

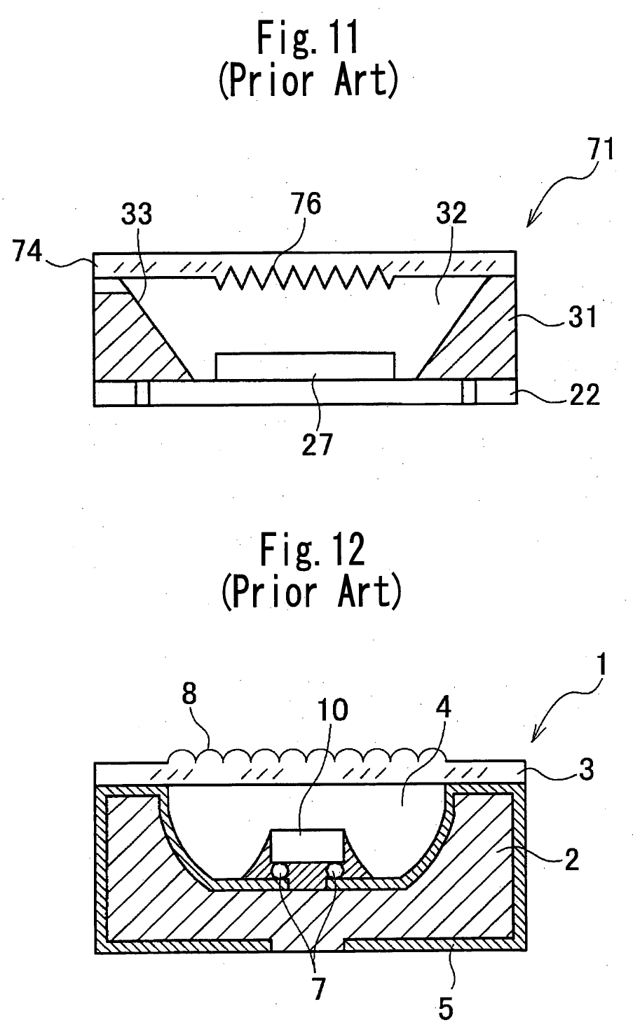

The main body 21 is formed by mounting the LED elements 28a to 28c on the circuit board 22 on which the anode electrodes A1 to A3 and cathode electrodes K1 to K3 are provided, sealing the LED elements with the resinous material 29, thereafter attaching the reflective frame 31 to the circuit board 22, as shown in FIG. 10.

In the above-mentioned main body 21, the brightness of the light emitted in a forward direction from the light emitter 27 can be significantly increased by a combination of the light emitted directly and upwardly from the light emitter 27 comprising the three LED elements 28a, 28b and 28c and the light reflected from the reflecting surface 33.

Moreover, as shown in FIG. 8, the light emitted from the light emitter 27 can be directed in a definite direction by focusing the light in the direction of travel thereof by the reflecting surface 33, as shown in FIG. 8, and the LED lamp can be mounted in a narrow space because the outline of the reflective frame 31 has generally the same size as the outline of the circuit board 22 in plane and there are no projections on the outer peripheral surfaces of the reflective frame and the circuit board.

Therefore, the LED lamp can be easily mounted on a mobile phone or other appliances in which a camera function is installed and a sufficient amount of light can be acquired when the LED lamp is used as a flash light source. Because each LED element contained in the light emitter 27 has a pair of separate electrodes A1 and K1, A2 and K2, A3 and K3, it is possible to achieve illumination of any one of the LED elements 28a, 28b or 28c, any two of the LED elements 28a and 28b or 28a and 28c or 28b and 28c, or all three LED elements 28a, 28b and 28c.

Meanwhile, in this embodiment, although the light emitter 27 comprises three LED elements 28a, 28b and 28c, the number of LED elements is not limited, so that a single LED element, two LED elements, or four or more LED elements may be used in accordance with the intended application.

The LED lamp 30 in this embodiment is formed by providing the translucent sealing plate 3 having the lens part 8 and disposed on the reflective frame 31 to contain an air layer 40 and the light emitter 27 in the concave portion 32 closed there by and disposing the protecting member 11 on the translucent sealing plate 3 around the emission area without shielding the emission area.

The protecting member 11 is provided to protect the lens part 8 of the translucent sealing plate 3 as described above and includes an opening 11a having an axis extending in a direction of thickness of the protecting member, an inner diameter of the opening 11a is set to be generally equal to a lens effective diameter 8a of the lens part 8 and an inner edge of the opening 11a is disposed to lie at an outer periphery of the lens effective diameter 8a.

The translucent sealing plate 3 includes a lens part 8 comprising a micro-lens, for example, formed on the emission area, and is made by formation of transparent or translucent resinous material or by directly molding a glass material into a predetermined shape. The translucent sealing plate 3 and the protecting member 11 may be formed integrally.

Because the air layer 40 is provided below the translucent sealing plate 3, the light emitted from the light emitter 27 passes through two media, the air layer 40 and the translucent sealing plate 3, which have different refractive indexes, before being emitted to the outside. A high focusing effect of light can be obtained by alteration of the refractive indexes.

In the LED lamp 30 in the embodiment, the concave portion is in a closed state, because the translucent sealing plate 3 is provided on the reflective frame 31. Therefore there is a concern that the air layer 40 in the concave portion 32 may inflate. In order to improve this point, an air hole 45 is provided to allow communication between the air layer 40 and the outside to reduce pressure in the concave portion. Thereby, reflow treatment is achieved safely and securely and deterioration in quality of the LED lamp can be reduced.

As described above, in the LED lamp 30 in the embodiment, the lens part 8 of the translucent sealing plate 3 is protected from external impacts to prevent any breakage of the lens part 8 or deterioration in the optical characteristics of the lens part. As a result, it is possible to achieve an LED lamp having excellent brightness characteristics and long-term reliability.

Meanwhile, in this embodiment, although the case has been described in which the lens part 8 is a micro-lens, it is not limited to this, and a similar effect-can be obtained even with a Fresnel lens or rough surface.

In addition, there are two structures for using the LED lamp in the embodiment as a flash light source which appears to emit white light.

The first structure is one in which blue light-emitting type-LED elements 28a, 28b and 28c are used in the light emitter 27 as shown in FIG. 9 and where, for example, YAG fluorescent materials are mixed in the resin sealing the LED elements.

The second structure is one in which red, green and blue light-emitting type-LED elements are used in the light emitter 27 and where white light-emission is obtained by adjusting the emission colors or brightness of light from the three LED elements.

In the first structure, it is possible to obtain the desired light-emitting color by combining fluorescent materials and/or colorant materials with at least one LED element. According to the second structure, it is possible to make various light-emitting colors and not be restricted to white light emission.

Moreover, by using the protecting members 12 or 13 in the first and second embodiments, instead of the protecting member 11, it is possible to increase the reflection efficiency of the light emitted from the lens part and the optical characteristics of the light.

Furthermore, by providing the translucent protecting plate 15 in the third embodiment on the protecting members 11, 12 or 13, dust is prevented from becoming attached to the lens part 8 of the translucent sealing plate 3, and hence deterioration in the optical characteristics of the lens part 8 can be prevented.

Moreover, even if the lens part 8 of the translucent sealing plate 3 is provided on the surface facing the light emitter 27, a similar effect to the other embodiments can be obtained.

In addition, the LED lamps in the above-mentioned embodiments emit visible light, but may also, may emit infrared or ultraviolet light.

Although the preferred embodiments of the present invention have been described, the present invention is not limited to the embodiments, and various changes and modifications can be made to the preferred embodiments.

What is claimed is:

1. A light-emitting diode lamp, comprising:
a circuit board;
a light emitter disposed on the circuit board;
a translucent sealing plate disposed above the light emitter; and
a protecting member for protecting the translucent sealing plate disposed on the translucent sealing plate.

2. The light-emitting diode lamp according to claim 1,
wherein the translucent sealing plate has a lens part.

3. The light-emitting diode lamp according to claim 1,
wherein the light emitter comprises at least one light-emitting element.

4. The light-emitting diode lamp according to claim 1,
further comprising a reflective frame disposed on the circuit board,
wherein the translucent sealing plate is disposed on the reflective frame.

5. The light-emitting diode lamp according to claim 1,
wherein the translucent sealing plate has a predetermined emission area, and the protecting member is disposed around the predetermined emission area without shielding light emitted from the emission area.

6. The light-emitting diode lamp according to claim 1,
wherein the protecting member has an opening which passes through the protecting member and which is larger than the emission area of the translucent sealing plate.

7. The light-emitting diode lamp according to claim 6,
wherein an inner diameter of the opening of the protecting member is set to become gradually larger from one side adjacent to the translucent sealing plate toward another side of the protecting member opposing the one side,
wherein the opening has a light reflecting layer formed on an inner surface of the opening.

8. The light-emitting diode lamp according to claim 6,
wherein the opening of the protecting member has an inner surface which has a generally truncated cone shape.

9. The light-emitting diode lamp according to claim 6,
wherein the opening of the protecting member has an inner surface which is curved.

10. The light-emitting diode lamp according to claim 7,
wherein the light reflecting layer provided on the inner surface of the opening is surface-treated by plating or vacuum evaporation in order to increase light-reflection efficiency.

11. The light-emitting diode lamp according to claim 1,
further comprising a translucent protecting plate disposed on an upper surface of the protecting member.

12. The light-emitting diode lamp according to claim 11,
wherein the translucent protecting plate comprises a sheet or flat plate made of a translucent resinous material or glass material.

13. The light-emitting diode lamp according to claim 11,
wherein an ultraviolet protection material is contained in the translucent protecting plate.

14. The light-emitting diode lamp according to claim 4,
wherein the circuit board and the reflective frame are formed as Molded Interconnection Devices.

15. The light-emitting diode lamp according to claim 4,
wherein the circuit board and the translucent sealing plate are formed by molded resin.

16. The light-emitting diode lamp according to claim 2,
wherein the translucent sealing plate and the protecting member are formed integrally.

17. The light-emitting diode lamp according to claim 1,
wherein the light emitter includes one or more LED elements and a transparent or translucent resinous body for sealing the LED elements.

18. The light-emitting diode lamp according to claim 1,
wherein the light emitter includes at least one blue light-emitting diode element, a resinous body sealing the blue light-emitting diode element, a fluorescent material mixed in the resinous body, and the light emitter appears to emit white light.

19. The light-emitting diode lamp according to claim 18,
wherein the fluorescent material includes yttrium, aluminum and garnet.

20. The light-emitting diode lamp according to claim 1,
wherein the light emitter comprises three kinds of red, green and blue light-emitting diode elements and a resinous body for sealing each of the light-emitting diode elements.

21. A light-emitting diode lamp, comprising:
a circuit board including electrode patterns;
a light emitter mounted on the circuit board;
a reflective frame disposed on the circuit board and having a reflecting surface formed to surround the light emitter;
a translucent sealing plate provided on an upper surface of the reflective frame and including a lens part; and
a protecting member disposed on the translucent sealing plate to protect at least the lens part,
the protecting member including an opening having an axis extending in a direction of thickness of the protecting member,
an inner edge of the opening being set to lie at an outer peripheral portion of a lens effective diameter of the lens part or outside the lens effective diameter.

22. A light-emitting diode lamp, comprising:
a circuit board including electrode patterns;
a light emitter disposed on the circuit board; and
a translucent sealing plate mounted on the circuit board and including a lens part,
the circuit board and the reflective frame being formed as Molded Interconnection Devices,
further comprising a protecting member provided to protect at least the lens part of the translucent sealing plate,
the protecting member including an opening having an axis extending in a direction of thickness of the protecting member,
an inner edge of the opening being set to lie at an outer peripheral portion of a lens effective diameter of the lens part or outside the lens effective diameter.
